(19) United States
(12) Patent Application Publication
(10) Pub. No.: US 2014/0131083 A1
(43) Pub. Date: May 15, 2014

(54) PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Sung Yeol Park, Suwon (KR); Suk Jin Ham, Suwon (KR); Jung Eun Noh, Suwon (KR)

(73) Assignee: SAMSUNG ELECTRO-MECHANICS CO., LTD., Suwon (KR)

(21) Appl. No.: 13/831,842

(22) Filed: Mar. 15, 2013

(30) Foreign Application Priority Data
Nov. 9, 2012 (KR) 10-2012-0126811

(51) Int. Cl. H05K 1/18; H05K 3/30

(52) U.S. Cl. CPC H05K 1/186; H05K 3/30
USPC 174/260; 29/832; 29/841

(57) ABSTRACT

Disclosed herein is a printed circuit board, including: a mounting substrate having a cavity formed therein; an electronic component inserted into the cavity; and a base substrate formed at least one of an upper part and a lower part of the electronic component, inserted into the cavity, and having an upper substrate pad and a lower substrate pad extended outwardly thereof and connected to each other.

### CROSS REFERENCE TO RELATED APPLICATION

This application claims the benefit of Korean Patent Application No. 10-2012-0126811, filed on Nov. 9, 2012, entitled “Printed Circuit Board and Method for Manufacturing the Same”, which is hereby incorporated by reference in its entirety into this application.

### BACKGROUND OF THE INVENTION

1. Technical Field

The present invention relates to a printed circuit board and a method for manufacturing the same.

2. Description of the Related Art

Generally, a circuit board includes various active elements or passive elements such as a resistor, a condenser, an inductor, a transformer, a filter, a mechanical switch, and a relay. Meanwhile, an electronic device has elements which are systematically connected to each other to perform their original functions, such that various passive elements or active elements configuring the electronic device perform their functions in the case in which power is applied to a circuit.

In particular, various technologies are also required in implementing a printed circuit board in accordance with the trend in which a market requires a profile reduction and various functions in a semiconductor package. Development of an embedded printed circuit board as part of a next generation package technology which is multi-functionalized and miniaturized has been recently prominent. In the embedded printed circuit board (PCB) (hereinafter, referred to as an “embedded board”), electronic components such as the passive elements or the active elements are inserted into an inner layer of the PCB to allow the PCB itself to perform roles of the electronic components. However, in manufacturing the printed circuit board in which the electronic components are embedded, reliability may be decreased due to a defect of an alignment between the embedded electronic component and an external circuit layer and a damage to an electrode in the case in which a via is formed in the electrode of the electronic component (U.S. Pat. No. 5,879,964).

### SUMMARY OF THE INVENTION

The present invention has been made in an effort to provide a printed circuit board and a method for manufacturing the same capable of omitting a via process for connecting electronic components to each other.

The present invention has been also made in an effort to provide a printed circuit board and a method for manufacturing the same capable of decreasing a defect due to a damage to an electrode of an embedded electronic component and an alignment error between the electronic component and a circuit layer.

According to a preferred embodiment of the present invention, there is provided a printed circuit board, including: a mounting substrate having a cavity formed therein; an electronic component inserted into the cavity; and
a base substrate formed at least one of an upper part and a lower part of the electronic component, inserted into the cavity, and having an upper substrate pad and a lower substrate pad extended outwardly thereof and connected to each other.

At least one of an upper part and a lower part of the electronic component may be provided with an electrode.

The printed circuit board may further include an electrode connecting part formed between the lower substrate pad of the base substrate and the electrode of the electronic component so as to attach the electronic component to the base substrate.

The electrode connecting part may be made of an electrical conductive metal.

An upper surface of the base substrate and an upper surface of the mounting substrate may be disposed on the same line.

The mounting substrate may further include at least one mounting pad formed on an upper part of an outer side of the cavity.

The mounting pad of the mounting substrate may contact the upper substrate pad of the base substrate so as to be electrically connected to each other.

The printed circuit board may further include a pad connecting part formed on the mounting pad and the upper substrate pad so as to electrically connect the mounting pad to the upper substrate pad.

The pad connecting part may be made of an electrical conductive metal.

The cavity may have the same size of a front cross section as that of a front cross section of the base substrate.

The printed circuit board may further include a molding part formed in the cavity.

According to another preferred embodiment of the present invention, there is provided a method for manufacturing a printed circuit board, the method including: preparing a base substrate having an upper substrate pad and a lower substrate pad extended outwardly thereof and connected to each other; attaching an electronic component to the lower substrate pad of the base substrate; providing a mounting substrate having a cavity formed therein; and mounting the base substrate to which the electronic component is attached in the cavity of the mounting substrate.

At least one of an upper part and a lower part of the electronic component may be provided with an electrode.

The attaching of the electronic component to the lower substrate pad of the base substrate may further include forming an electrode connecting part attaching an electrode of the electronic component to the lower substrate pad of the base substrate.

The electrode connecting part may be made of an electrical conductive metal.

The electrode connecting part may be formed on the lower substrate pad by a plating method.

In the providing of the mounting substrate having the cavity formed therein, the cavity may have the same size of a front cross section as that of a front cross section of the base substrate.

In the mounting of the base substrate to which the electronic component is attached in the cavity of the mounting substrate, an upper surface of the base substrate and an upper surface of the mounting substrate may be formed so as to be disposed on the same line.

The providing of the mounting substrate having the cavity formed therein may further include forming at least one mounting pad on an upper part of an outer side of the cavity of the mounting substrate.

In the mounting of the base substrate to which the electronic component is attached in the cavity of the mounting substrate, the mounting pad of the mounting substrate may contact the upper substrate pad of the base substrate so as to be electrically connected to each other.

The method may further include, after the mounting of the base substrate to which the electronic component is attached in the cavity of the mounting substrate, forming a pad connecting part formed on the mounting pad and the upper substrate pad and electrically connecting the mounting pad to the upper substrate pad.

In the forming of the pad connecting part, the pad connecting part may be made of an electrical conductive metal.

The method may further include, after the attaching of the electronic component to the lower substrate pad of the base substrate, forming a molding part enclosing the electronic component, at a lower part of the base substrate.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a diagram showing a printed circuit board according to a preferred embodiment of the present invention;

FIG. 2 is a diagram showing a printed circuit board according to another preferred embodiment of the present invention; and

FIGS. 3 to 8 are diagrams showing a method for manufacturing the printed circuit board according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

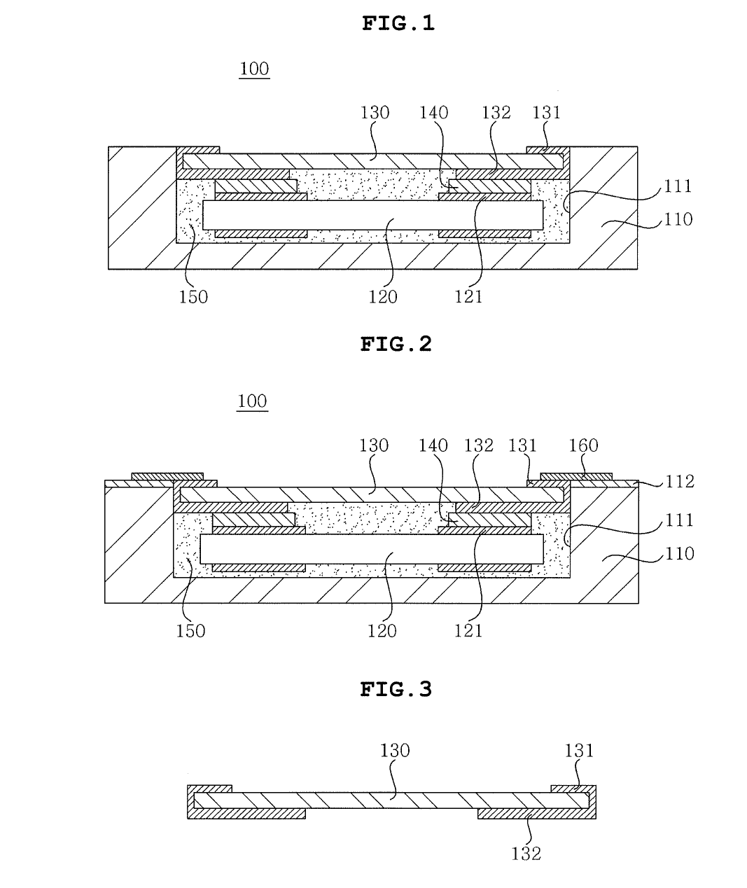

FIG. 1 is a diagram showing a printed circuit board according to a preferred embodiment of the present invention.

Referring to FIG. 1, a printed circuit board 100 may include a mounting substrate 110, an electronic component 120, and a base substrate 130.

The mounting substrate 110 may have a cavity 111 formed therein. The mounting substrate 110 may be made of a general insulating material which is applied to a field of the printed circuit board. In addition, although not shown, the mounting substrate 110 may have one or more circuit layers formed on the insulating material. As the insulating material, a thermo-setting resin such as an epoxy resin, a thermo-plastic resin such as a polyimide or a resin having a reinforcement material such as glass fiber or an inorganic filler impregnated therein, for example, a prepreg may be used. In addition, the insulating material may be a photo-setting resin and the like, but is not specifically limited thereto. According to the preferred embodiment of the present invention, the cavity 111 is a region which is perforated in order to embed the electronic component 120 and the base substrate 130 in the mounting substrate 110. A size of the cavity 111 may be determined so that the to mounting substrate 110 and the base substrate 130 may be embedded. For example, a depth of the cavity may be equal to or larger than a total depth at which the electronic component 120 is mounted on the base substrate 130. In addition, the cavity 111 may have the same shape and size of a front cross section as that of a front cross section of the base substrate 130.

The electronic component 120 may be a part which may be electrically connected to the printed circuit board 100 so as to serve a predetermined function. At least one of an upper part and a lower part of the electronic component 120 may be provided with an electrode 121. The electrode 121 may be a configuration part of performing an electrical connection between the printed circuit board and the electronic component 120. In the preferred embodiment of the present invention, the electrode 121 of the electronic component 120 may be electrically connected to a lower substrate pad 132 of the base substrate 130. In addition, the electronic components 120 may be attached to the base substrate 130 so as to be embedded in the cavity 111 of the mounting substrate 110.

The base substrate 130 may be formed at least one of an upper part and a lower part of the electronic component 120. The base substrate 130 may include an upper substrate pad 131 and the lower substrate pad 132. Similar to the mounting substrate 110, the base substrate 130 may be made of the insulating material. The upper substrate pad 131 and the lower substrate pad 132 may be extended outwardly of the base substrate 130 and be connected to each other. The lower substrate pad 132 of the base substrate 130 may be attached to the electrode 121 of the electronic component 120. In this configuration, the lower substrate pad 132 and the electrode of the electronic component 120 may be attached to each other through an electrode connecting part 140. The electrode connecting part 140 may be made of an electrical conductive metal. The electrode connecting part 140 may be formed by a plating method or the like. The base substrate 130 to which the electronic component 120 is attached may be embedded in the cavity 111 of the mounting substrate 110. Here, an upper surface of the base substrate 130 may be disposed on the same line as an upper surface of the mounting substrate 110. Although FIG. 1 shows a case in which the base substrate 130 has the upper substrate pad 131 and the lower substrate pad 132 formed thereon, the present invention is not limited thereto. That is, the base substrate 130 may have another circuit pattern or the like other than the upper substrate pad 131 and the lower substrate pad 132 formed thereon.

Although not shown, the printed circuit board according to the preferred embodiment of the present invention may further have at least one build-up layer (not shown) including an insulating layer and a circuit layer, formed on the base substrate and the mounting substrate. The above-mentioned build-up layer (not shown) may be connected to the electronic component 120 through the lower substrate pad 132 and the upper substrate pad 131 of the base substrate 130.

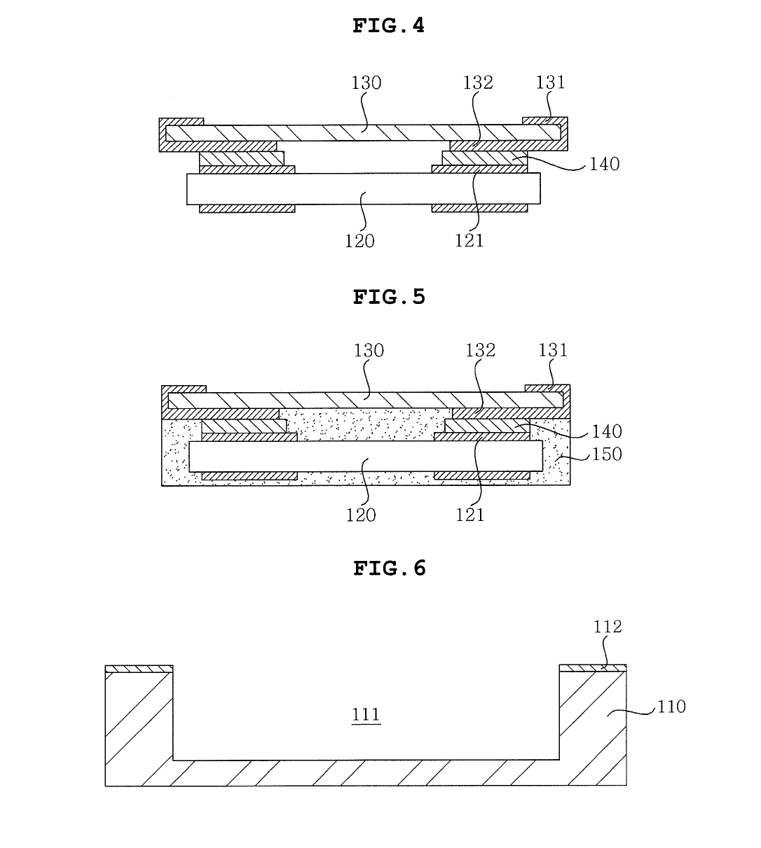

FIG. 2 is a diagram showing a printed circuit board according to another preferred embodiment of the present invention.

Referring to FIG. 2, a printed circuit board 100 may include a mounting substrate 110, an electronic component 120, and a molding part 150.

The mounting substrate 110 may have a cavity 111 formed therein. The mounting substrate 110 may be made of a general insulating material which is applied to a field of the printed circuit board. In addition, although not shown, the mounting substrate 110 may have one or more circuit layers formed on the insulating material. As the insulating material, a thermo-setting resin such as an epoxy resin, a thermo-plastic resin such as a polyimide or a resin having a reinforcement material such as glass fiber or an inorganic filler impregnated therein, for example, a prepreg may be used. In addition, the insulating material may be a photo-setting resin and the like, but is not specifically limited thereto. According to the preferred embodiment of the present invention, the cavity 111 is a region which is perforated in order to embed the electronic component 120 and the base substrate 130 in the mounting substrate 110. A size of the cavity 111 may be determined so that the mounting substrate 110 and the base substrate 130 may be embedded. For example, a depth to of the cavity may be equal to or larger than a total depth at which the electronic component 120 is mounted on the base substrate 130. In addition, the cavity 111 may have the same shape and size of a front cross section as that of a front cross section of the base substrate 130. At least one mounting pad 112 may be formed on an upper part of an outer side of the cavity 111 of the mounting substrate 110.

The electronic component 120 may be a part which may be electrically connected to the printed circuit board 100 so as to serve a predetermined function. At least one of an upper part and a lower part of the electronic component 120 may be provided with an electrode 121. The electrode 121 may be a configuration part of performing an electrical connection between the printed circuit board and the electronic component 120. In the preferred embodiment of the present invention, the electrode 121 of the electronic component 120 may be electrically connected to a lower substrate pad 132 of the base substrate 130. In addition, the electronic components 120 may be attached to the base substrate 130 so as to be embedded in the cavity 111 of the mounting substrate 110.

The base substrate 130 may be formed at least one of an upper part and a lower part of the electronic component 130 may include an upper substrate pad 131 and the lower substrate pad 132. Similar to the mounting substrate 110, the base substrate 130 may be made of the insulating material. The upper substrate pad 131 and the lower substrate pad 132 may be extended outwardly of the base substrate 130 and be connected to each other. The lower substrate pad 132 of the base substrate 130 may be attached to the electrode 121 of the electronic component 120. In this configuration, the lower substrate pad 132 and the electrode of the electronic component 120 may be attached to each other through an electrode connecting part 140. The electrode connecting part 140 may be made of an electrical conductive metal. The electrode connecting part 140 may be formed by a plating method or the like. The base substrate 130 to which the electronic component 120 is attached may be embedded in the cavity 111 of the mounting substrate 110. Here, an upper surface of the base substrate 130 may be disposed on the same line as an upper surface of the mounting substrate 110. That is, the upper substrate pad 131 of the base substrate 130 may be disposed on the same line as the mounting pad 112 of the mounting substrate 110. In addition, in the case in which the base substrate 130 is mounted in the cavity 111, the upper substrate pad 131 may contact the mounting pad 112 so as to be electrically connected to each other. Alternatively, the upper substrate pad 131 and the mounting pad 112 may be electrically connected to each other by a pad connecting part 160. The pad connecting part 160 may be formed on the upper substrate pad 131 and the mounting pad 112. The pad connecting part 160 may be made of the electrical conductive metal. Although FIG. 2 shows a case in which the base substrate 130 has the upper substrate pad 131 and the lower substrate pad 132 formed thereon, the present invention is not limited thereto. That is, the base substrate 130 may have another circuit pattern or the like other than the upper substrate pad 131 and the lower substrate pad 132 formed thereon.

The molding part 150 may be formed in the cavity 111. The molding part 150 may be formed so as to protect the electronic component 120 embedded in the mounting substrate 110 from external impact. The molding part 150 may be made of a general molding material such as the epoxy resin or silicon gel.

Although not shown, the printed circuit board according to the preferred embodiment of the present invention may further include at least one build-up layer (not shown) including an insulating layer and a circuit layer, formed on the base substrate and the mounting substrate. The above-mentioned build-up layer (not shown) may be electrically connected to the electronic component 120 through the lower substrate pad 132 and the upper substrate pad 131 of the base substrate 130.

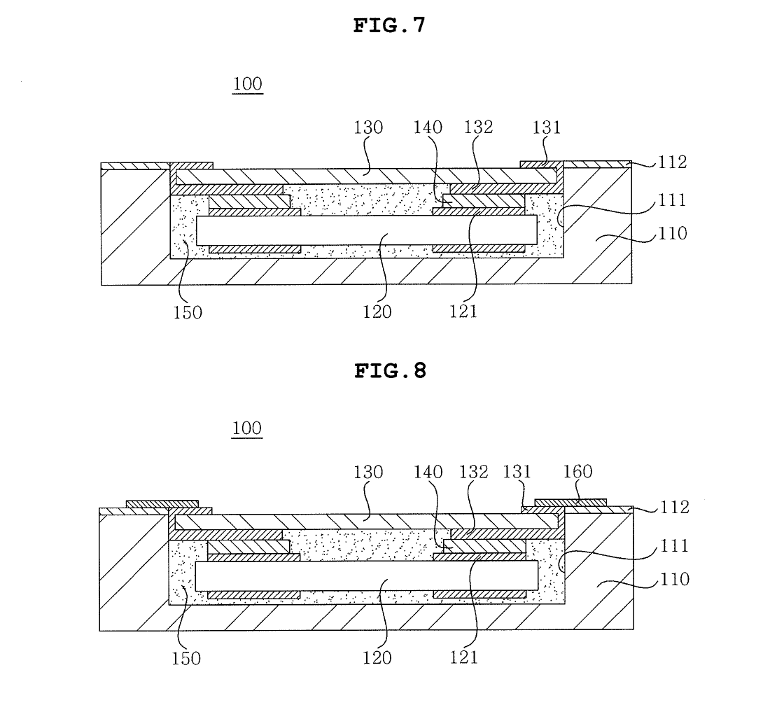

FIGS. 3 to 8 are diagrams showing a method for manufacturing the printed circuit board according to a preferred embodiment of the present invention.

Referring to FIG. 3, the base substrate 130 may be prepared. The base substrate 130 may include an upper substrate pad 131 and the lower substrate pad 132. The base substrate 130 may be made of the insulating material. As the insulating material, a thermo-setting resin such as an epoxy resin, a thermo-plastic resin such as a polyimide or a resin having a reinforcement material such as glass fiber or an inorganic filler impregnated therein, for example, a prepreg may be used. In addition, the insulating material may be a photo-setting resin and the like, but is not specifically limited thereto. The base substrate 130 may include the upper substrate pad 131 and the lower substrate pad 132. The upper substrate pad 131 and the lower substrate pad 132 may be extended outwardly of the base substrate 130 and be connected to each other.

Although not shown in the present invention, the base substrate 130 may have another circuit pattern or the like other than the upper substrate pad 131 and the lower substrate pad 132 formed thereon.

Referring to FIG. 4, the electronic component 120 may be attached to the lower substrate pad 132 of the base substrate 130. The electronic component 120 may be a part which may be electrically connected to the printed circuit board 100 so as to serve a predetermined function. At least one of an upper part and a lower part of the electronic component 120 may be provided with an electrode 121. The electrode 121 may be a configuration part of performing an electrical connection between the printed circuit board and the electronic component 120. The electrode 121 of the electronic component 120 and the lower substrate pad 132 of the base substrate 130 may be electrically connected to each other. In this configuration, the lower substrate pad 132 and the electrode of the electronic component 120 may be attached to each other through an electrode connecting part 140. That is, the electronic component 120 may be attached to a lower portion of the base substrate 130 by the electrode connecting part 140. The electrode connecting part 140 may be made of an electrical conductive metal. The electrode connecting part 140 may be formed on the lower substrate pad 132 of the base substrate 130 by the plating method. Alternatively, the electrode connecting part 140 may be formed on the electrode 121 of the electronic component 120 by the plating method.

Referring to FIG. 5, the molding part 150 may be formed. The molding part 150 may be formed so as to protect the electronic component 120 embedded in the mounting substrate 110 from external impact. The molding part 150 may be formed at the lower part of the base substrate 130 and may be formed so as to enclose the electronic component 120. The molding part 150 may be made of a general molding material such as the epoxy resin or silicon gel. The molding part 150 may have a size and a shape formed so as to correspond to the cavity 111 of the mounting substrate 110. According to the preferred embodiment of the present invention, the order of forming the molding part may be changed by those skilled in the art. In addition, a method and material of forming the molding part 150 may also be changed by those skilled in the art by applying already known technologies. In addition, the forming of the molding part may be omitted by a selection of those skilled in the art.

Referring to FIG. 6, the mounting substrate 110 may be provided. The mounting substrate 110 may be made of the insulating material. In addition, the mounting substrate 110 may have a cavity 111 formed therein. As the insulating material, a thermo-setting resin such as an epoxy resin, a thermo-plastic resin such as a polyimide or a resin having a reinforcement material such as glass fiber or an inorganic filler impregnated therein, for example, a prepreg may be used. In addition, the insulating material may be a photo-setting resin and the like, but is not specifically limited thereto. In addition, although not shown, the mounting substrate 110 may have one or more circuit layers formed on the insulating material. For example, at least one mounting pad 112 may be formed on an upper part of an outer side of the cavity 111 of the mounting substrate 110.

The cavity 111 is a region which is perforated in order to embed the electronic component 120 and the base substrate 130 in the mounting substrate 110. The method of forming the cavity 111 is not specifically limited. For example, the cavity 111 may be formed by a laser drill. A size of the cavity 111 may be determined so that the mounting substrate 110 and the base substrate 130 may be embedded. For example, a depth of the cavity may be equal to or larger than a total depth at which the electronic component 120 is mounted on the base substrate 130. In addition, the cavity 111 may have the same shape and size of a front cross section as that of a front cross section of the base substrate 130.

Referring to FIG. 7, the base substrate 130 in which the electronic component 120 is attached to the cavity 111 of the mounting substrate 110 may be mounted. In the case in which the base substrate 130 is mounted in the mounting substrate 110, it is possible to embed the electronic component 120 in the cavity 111. Here, an upper surface of the base substrate 130 may be disposed on the same line as an upper surface of the mounting substrate 110. That is, the upper substrate pad 131 of the base substrate 130 may be disposed on the same line as the mounting pad 112 of the mounting substrate 110. In addition, in the case in which the base substrate 130 is mounted in the cavity 111, the upper substrate pad 131 may contact the mounting pad 112 so as to be electrically connected to each other. The pad connecting part 160 may be formed on the upper substrate pad 131 and the mounting pad 112. The pad connecting part 160 may be made of the electrical conductive metal.

Referring to FIG. 8, the pad connecting part 160 may be formed. The pad connecting part 160 may electrically connect the mounting pad 112 of the mounting substrate 110 to the upper substrate pad 131 of the base substrate 130. The pad connecting part 160 may be formed by a plating method or the like. The reliability of the electrical connection between the base substrate 130 and the base substrate 130 may be improved by the pad connecting part 160 formed as described above.

The printed circuit board having the electronic component embedded therein and the method for manufacturing the same according to the preferred embodiment of the present invention may include the base substrate in which the upper substrate pad and the lower substrate pad are extended outwardly and be connected to each other. As described above, the upper substrate pad of the base substrate electrically connected to the electronic component is exposed, thereby making it possible to omit the process of forming the via for the electrical connection between the build-up layer and the electronic component. In addition, the process of forming the via for the electrical connection between the electronic component embedded by the base substrate and the build-up layer is omitted, thereby making it possible to solve the problem due to the damage to the electrode and the alignment error occurring at the time of the process of forming the via.

With the printed circuit board and the method for manufacturing the same according to the preferred embodiments of the present invention, the via process for connecting the electronic components to each other may be omitted.

With the printed circuit board and the method for manufacturing the same according to the preferred embodiments of the present invention, the defect due to the damage to the electrode of the embedded electronic component and the alignment error between the electronic component and the circuit layer may be decreased.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A printed circuit board, comprising:
a mounting substrate having a cavity formed therein;
an electronic component inserted into the cavity; and
a base substrate formed on at least one of an upper part and a lower part of the electronic component, inserted into the cavity, and having an upper substrate pad and a lower substrate pad extended outwardly thereof and connected to each other.

2. The printed circuit board as set forth in claim 1, wherein at least one of an upper part and a lower part of the electronic component is provided with an electrode.

3. The printed circuit board as set forth in claim 2, further comprising an electrode connecting part formed between the lower substrate pad of the base substrate and the electrode of the electronic component so as to attach the electronic component to the base substrate.

4. The printed circuit board as set forth in claim 3, wherein the electrode connecting part is made of an electrical conductive metal.

5. The printed circuit board as set forth in claim 1, wherein an upper surface of the base substrate and an upper surface of the mounting substrate are disposed on the same line.

6. The printed circuit board as set forth in claim 1, wherein the mounting substrate further includes at least one mounting pad formed on an upper part of an outer side of the cavity.

7. The printed circuit board as set forth in claim 6, wherein the mounting pad of the mounting substrate contacts the upper substrate pad of the base substrate so as to be electrically connected to each other.

8. The printed circuit board as set forth in claim 6, further comprising a pad connecting part formed on the mounting pad and the upper substrate pad so as to electrically connect the mounting pad to the upper substrate pad.

9. The printed circuit board as set forth in claim 8, wherein the pad connecting part is made of an electrical conductive metal.

10. The printed circuit board as set forth in claim 1, wherein the cavity has the same size of a front cross section as that of a front cross section of the base substrate.

11. The printed circuit board as set forth in claim 1, further comprising a molding part formed in the cavity.

12. A method for manufacturing a printed circuit board, the method comprising:
preparing a base substrate having an upper substrate pad and a lower substrate pad are extended outwardly thereof and connected to each other;
attaching an electronic component to the lower substrate pad of the base substrate;
providing a mounting substrate having a cavity formed therein; and
mounting the base substrate to which the electronic component is attached in the cavity of the mounting substrate.

13. The method as set forth in claim 12, wherein at least one of an upper part and a lower part of the electronic component is provided with an electrode.

14. The method as set forth in claim 13, wherein the attaching of the electronic component to the lower substrate pad of the base substrate further includes forming an electrode connecting part attaching an electrode of the electronic component to the lower substrate pad of the base substrate.

15. The method as set forth in claim 14, wherein the electrode connecting part is made of an electrical conductive metal.

16. The method as set forth in claim 14, wherein the electrode connecting part is formed on the lower substrate pad by a plating method.

17. The method as set forth in claim 12, wherein in the providing of the mounting substrate having the cavity formed therein, the cavity has the same size of a front cross section as that of a front cross section of the base substrate.

18. The method as set forth in claim 12, wherein in the mounting of the base substrate to which the electronic component is attached in the cavity of the mounting substrate, an upper surface of the base substrate and an upper surface of the mounting substrate are formed so as to be disposed on the same line.

19. The method as set forth in claim 12, wherein the providing of the mounting substrate having the cavity formed therein further includes forming at least one mounting pad on an upper part of an outer side of the cavity of the mounting substrate.

20. The method as set forth in claim 19, wherein in the mounting of the base substrate to which the electronic component is attached in the cavity of the mounting substrate, the mounting pad of the mounting substrate contacts the upper substrate pad of the base substrate so as to be electrically connected to each other.

21. The method as set forth in claim 19, further comprising, after the mounting of the base substrate to which the electronic component is attached in the cavity of the mounting substrate, forming a pad connecting part formed on the mounting pad and the upper substrate pad and electrically connecting the mounting pad to the upper substrate pad.

22. The method as set forth in claim 21, wherein in the forming of the pad connecting part, the pad connecting part is made of an electrical conductive metal.

23. The method as set forth in claim 12, further comprising, after the attaching of the electronic component to the lower substrate pad of the base substrate, forming a molding part enclosing the electronic component, at a lower part of the base substrate.
